(19) United States
(12) Patent Application Publication
(10) Pub. No.: US 2024/0107903 A1
(43) Pub. Date: Mar. 28, 2024

(54) MEMORY DEVICE AND MANUFACTURING METHOD THEREOF

(71) Applicants: TAIWAN SEMICONDUCTOR MANUFACTURING COMPANY, LTD., Hsinchu (TW); NATIONAL TAIWAN UNIVERSITY, TAIPEI (TW)

(72) Inventors: Shih-Yen LIN, New Taipei City (TW); Po-Cheng TSAI, Taichung City (TW)

(73) Assignees: TAIWAN SEMICONDUCTOR MANUFACTURING COMPANY, LTD., Hsinchu (TW); NATIONAL TAIWAN UNIVERSITY, TAIPEI (TW)

(21) Appl. No.: 18/182,991

(22) Filed: Mar. 13, 2023

Related U.S. Application Data
(60) Provisional application No. 63/410,378, filed on Sep. 27, 2022.

(51) Int. Cl. H10N 70/00; H10B 63/00

(52) U.S. Cl. CPC H10N 70/882; H10B 63/34; H10N 70/063

(57) ABSTRACT

A memory device includes a substrate, a 2-D material channel layer, a 2-D material charge storage layer, source/drain contacts, a gate dielectric layer, and a gate electrode. The 2-D material channel layer is over the substrate. The 2-D material charge storage layer is over the 2-D material channel layer. The 2-D charge storage layer and the 2-D material channel layer include the same chalcogen atoms. The source/drain contacts are over the 2-D material channel layer. The gate dielectric layer covers the source/drain contacts and the 2-D material charge storage layer. The gate electrode is over the gate dielectric layer.

### PRIORITY CLAIM AND CROSS-REFERENCE

The present application claims priority to U.S. Provisional Application Ser. No. 63/410,378, filed Sep. 27, 2022, which is herein incorporated by reference.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 2-7 illustrate cross-sectional views of intermediate stages in the formation of a memory device in accordance with some embodiments of the present disclosure.

FIG. 1B illustrates a molecular diagram of a transition metal dichalcogenide compound according to some embodiments of the present disclosure.

FIG. 8 illustrates a cross-sectional view of a memory device in accordance with some embodiments of the present disclosure.

FIG. 9 illustrates a cross-sectional view of a memory device in accordance with some embodiments of the present disclosure.

FIG. 10A illustrates an I_{D}-V_{GS} curve of the memory device shown in FIG. 8.

FIG. 10B illustrates an I_{D}-V_{GS} curve of the memory device shown in FIG. 9.

FIG. 11 illustrates an I_{D}-Measurement time curve of the memory device shown in FIG. 10B.

FIG. 12 illustrates a current ratio-V_{GS} curve of the memory devices shown in FIGS. 8 and 9.

FIG. 13 illustrates an I_{D}-Measurement time curve of the memory device shown in FIG. 9.

FIGS. 14A, 14B, 14C, and 14D illustrate current conduction mechanism at different stages in accordance with some embodiments of the present disclosure.

FIG. 15 illustrates a cross-sectional view of a memory device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated. As used herein, the term “conductive” refers to an electrically conductive structure, layer, and/or region. As used herein, source/drain region(s) may refer to a source or a drain, individually or collectively dependent upon the context.

Some embodiments of the present disclosure are related to memory devices and methods of forming the same. More particularly, some embodiments of the present disclosure are related to memory devices including 2-D material channel layer(s) and 2-D material charge storage layer(s) with similar band gaps. Long retention times for the “0” and “1” states can be observed.

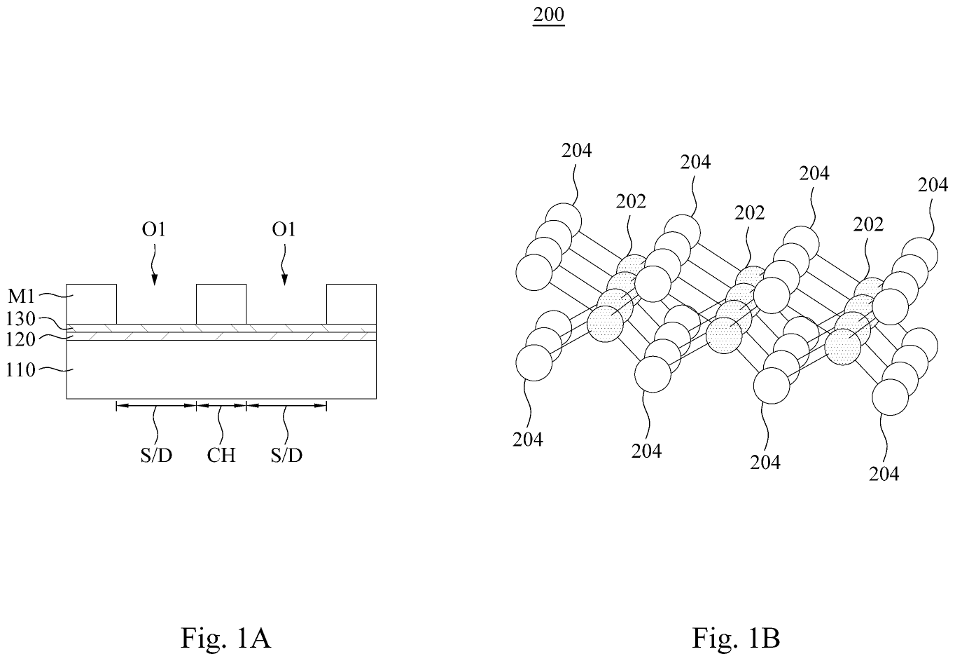

FIGS. 1A and 2-7 illustrate cross-sectional views of intermediate stages in the formation of a memory device 100a in accordance with some embodiments of the present disclosure. Referring to FIG. 1A, a substrate 110 is provided. In some embodiments, the substrate 110 may function to provide mechanical and/or structure support for features or structures that are formed in the subsequent operations. These features or structures may be parts or portions of a memory device that may be formed on or over the substrate 110.

The substrate 110 illustrated in FIG. 1A may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor may include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates. In some other embodiments, the substrate 110 may include sapphire (e.g. crystalline Al₂O₃), e.g. a large grain or a single crystalline layer of sapphire or a coating of sapphire. As another example, the substrate 110 may be a sapphire substrate, e.g. a transparent sapphire substrate including, as an example, α-Al₂O₃. Other elementary semiconductors like germanium may also be used for substrate 110.

A 2-D material layer 120 is formed over the substrate 110, and a 2-D material layer 130 is formed over the 2-D material layer 120. In some embodiments, the 2-D material layer 120 is in direct contact with the top surface of the substrate 110. As used herein, consistent with the accepted definition within solid state material art, a “2-D material” may refer to a crystalline material consisting of a single layer of atoms. As widely accepted in the art, “2-D material” may also be referred to as a “mono-layer” material. In this disclosure, “2-D material” and “mono-layer” material are used interchangeably without differentiation in meanings, unless specifically pointed out otherwise. The 2-D material layer 120 may be 2-D materials of suitable thickness. In some embodiments, a 2-D material includes a single layer of atoms in each of its mono-layer structure, so the thickness of the 2-D material refers to a number of mono-layers of the 2-D material, which can be one mono-layer or more than one mono-layer. The coupling between two adjacent mono-layers of 2-D material includes van der Waals forces, which are weaker than the chemical bonds between/among atoms within the single mono-layer.

In some embodiments, the 2-D material layer 120 and the 2-D material layer 130 may be 2-D semiconductor materials, which are usually few-layer thick and exist as stacks of strongly bonded layers with weak interlayer van der Waals attraction, allowing the layers to be mechanically or chemically exfoliated into individual, atomically thin layers. Examples of 2-D semiconductor materials include transition metal dichalcogenides (TMDs), layered III-VI chalcogenide, hexagonal Boron Nitride (h-BN), black phosphorus or the like. The 2-D semiconductor materials may include one or more layers. One advantageous feature of the few-layered 2D semiconductor is the high electron mobility value.

FIG. 1B illustrates a molecular diagram 200 of a transition metal dichalcogenide compound (e.g., the 2-D material layer 120 and the 2-D material layer 130) according to some embodiments of the present disclosure. The one-molecule thick TMD material layer includes atoms 202 of a transition metal and atoms 204 of a chalcogenide. The transition metal atoms 202 may form a layer in a middle region of the one-molecule thick TMD material layer, and the chalcogen atoms 204 may form a first layer over the middle layer of transition metal atoms 202, and a second layer underlying the middle layer of transition metal atoms 204. The transition metal atoms 202 may be W atoms or Mo atoms, while the chalcogen atoms 204 may be S atoms, Se atoms, or Te atoms. Throughout the description, the illustrated cross-bonded layers including one layer of transition metal atoms 202 and two layers of chalcogen atoms 204 in combination are referred to as a mono-layer of TMD. The transition metal dichalcogenide materials align in generally planar mono-layers and exhibit high conductivity and carrier mobility.

Referring back to FIG. 1A, the 2-D material layer 120 and the 2-D material layer 130 may be made of the same 2-D materials. For example, the 2-D material layer 120 and the 2-D material layer 130 are both made of molybdenum disulfide (MoS₂) layers, or molybdenum diselenide (MoSe₂) layers, or tungsten disulfide (WS₂) layers, or tungsten diselenide (WSe₂) layers. In some other embodiments, the 2-D material layer 120 and the 2-D material layer 130 are made of different 2-D materials (e.g., hetero-structures). For example, the 2-D material layer 120 and the 2-D material layer 130 are respectively made of MoS₂ and WS₂, or WS₂ and MoS₂, or MoSe₂ and WSe₂, or WSe₂ and MoSe₂. Stated another way, the 2-D material layer 120 and the 2-D material layer 130 include the same chalcogen atoms. However, the 2-D material layer 120 and the 2-D material layer 130 may include the same or different transition metals. In some other embodiments, the 2-D material layer 120 and the 2-D material layer 130 may be made of other suitable 2-D materials.

In some embodiments, the 2-D material layer 120 may have a band gap substantially the same or slightly lower than a band gap of the 2-D material layer 130. For example, a difference between the band gaps of the 2-D material layer 120 and the 2-D material layer 130 is smaller than about 0.5 eV. Further, the band gaps of the 2-D material layer 120 and the 2-D material layer 130 are both in a range from about 1 eV to about 3 eV, e.g., about 1 eV to about 2 eV.

In some embodiments, MoS₂ and WS₂ may be formed over the substrate 110, using suitable approaches. For example, MoS₂ and WS₂ may be formed by micromechanical exfoliation and coupled over the substrate 110 or the 2-D material layer 120, or by sulfurization of a pre-deposited molybdenum (Mo) film or tungsten (W) film over the substrate 110 or the 2-D material layer 120. In alternative embodiments, WSe₂ may be formed by micromechanical exfoliation and coupled over the substrate 110 or the 2-D material layer 120, or by selenization of a pre-deposited tungsten (W) film over the substrate 110 or the 2-D material layer 120 using thermally cracked Se molecules. It is possible to further reduce the growth temperature of TMDs to lower than about 500° C.

In some other embodiments where MoS₂ is formed by micromechanical exfoliation, the 2-D material layer 120 and/or the 2-D material layer 130 is/are formed on another substrate and then transferred to the substrate 110 or the 2-D material layer 120. For example, a 2-D material film is formed on a first substrate by chemical vapor deposition (CVD), sputtering, or atomic layer deposition (ALD) in some embodiments. A polymer film, such as poly(methyl methacrylate) (PMMA), is subsequently formed on the 2-D material film. After forming the polymer film, the sample is heated, such as by placing the sample on a hot plate. Subsequent to heating, a corner of the 2-D material film is peeled off the first substrate, such as by using a tweezers, and the sample is submerged in a solution to facilitate the separation of the 2-D material film from the first substrate. The 2-D material film and polymer film are transferred to the substrate 110 or the 2-D material layer 120. The polymer film is then removed from the 2-D material film using a suitable solvent.

In some embodiments, the 2-D material layer 120 and the 2-D material layer 130 may be formed by suitable deposition process without using plasma treatment. For example, the deposition process using plasma treatment may include RF sputtering. In some embodiments, the 2-D material layer 120 and the 2-D material layer 130 may be formed by thermal evaporation. For example, a MoO₃ layer is deposited over the substrate 110 or the 2-D material layer 120, and then performing a sulfurization process to the MoO₃ film using the thermal evaporator. In some embodiment, MoO₃ powders are spin coated over the substrate 110 or the 2-D material layer 120, and the sulfurization process is performed at a temperature in a range between about 600° C. to about 900° C. Alternatively, plasma with H₂S gas flow is the sulfur source for sulfurization, and the sulfurization temperature is in a range between about 300° C. to about 500° C. In some embodiments, similar growth techniques without using plasma treatment, such as molecular beam epitaxy (MBE), atomic layer deposition (ALD) and e-gun evaporation, may also be adopted for the deposition of the 2-D material layer 120 and the 2-D material layer 130.

In some embodiments, the 2-D material layer 120 may act as a channel layer (referred to as a 2-D material channel layer), in which the 2-D material layer 120 may include a channel region CH and source/drain regions S/D on opposite sides of the channel region CH. In some embodiments, the 2-D material layer 130 may act as a charge storage layer (referred to as a 2-D charge storage layer) between the 2-D material layer 120 and a gate dielectric layer of a gate structure (e.g., the gate dielectric layer 152 of the gate structure 150 of FIG. 7). In some embodiments, the length of the channel region CH is in a range from about 3 um to about 7 um, and the width of the channel region CH is in a range from about 35 um to about 45 um.

A patterned mask M1 is formed over the 2-D material layer 130. The patterned mask M1 may include openings O1 that substantially align with the source/drain regions S/D of the 2-D material layer 120. In some embodiments, the patterned mask M1 may be a photoresist, a hard mask, or suitable materials, and may be patterned using a photolithography technique.

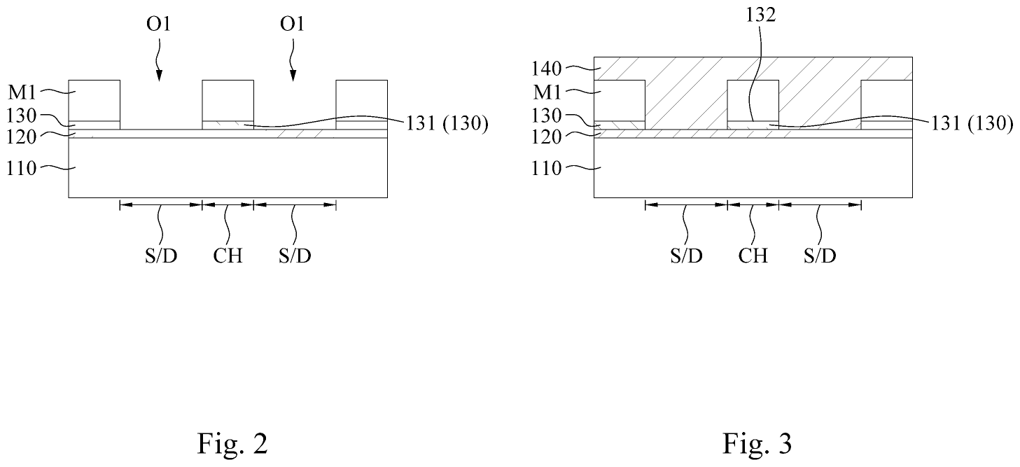

Reference is made to FIG. 2. An etching process is performed to remove portions of the 2-D material layer 130 through the openings O1 of the patterned mask M1. The 2-D material layer 130 includes at least a remaining portion 131 substantially overlapping the channel region CH of the 2-D material layer 120.

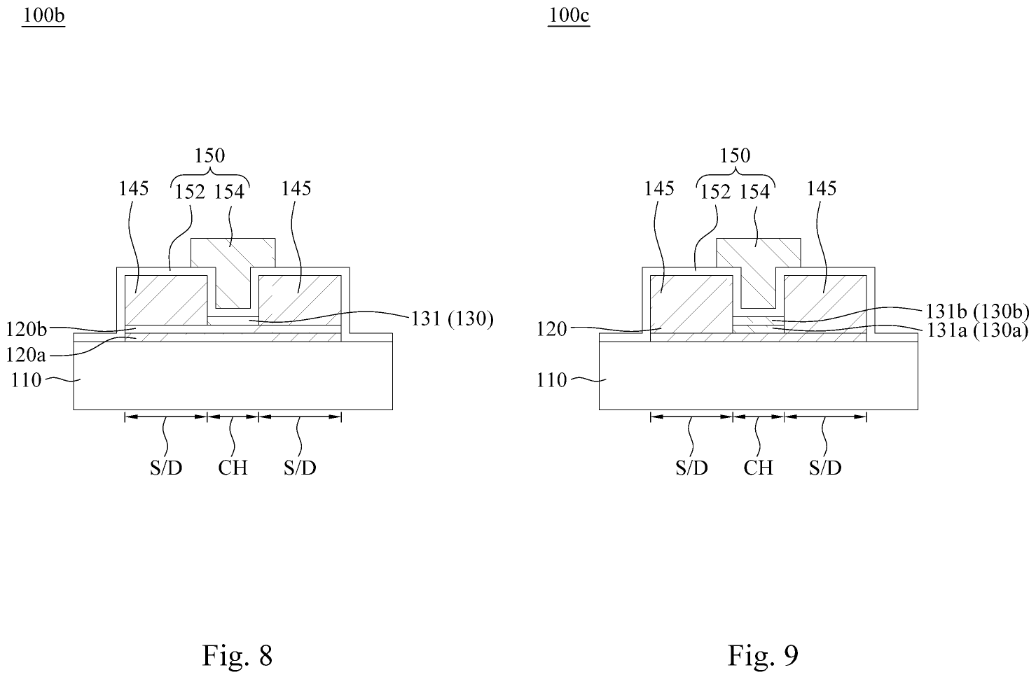

In some embodiments, the etching process may include an atomic layer etching (ALE) process. In some embodiments where the 2-D material layer 130 is made of MoS₂, the ALE process is a layered removal mechanism of MoS₂ using low-power oxygen plasma. Each ALE cycle includes a low-power oxygen plasma treatment, a dipping procedure, and a re-sulfurization procedure. During the low-power oxygen plasma treatment, the topmost MoS₂ mono-layer is oxidized. This will result in a weaker adhesion of Mo oxides with underlying MoS₂ surfaces, which may lead to detachment of the topmost oxidized MoS₂ layer from the underlying MoS₂ films. Afterward, the dipping procedure is performed to remove the topmost oxidized MoS₂ layer. Since MoS₂ is insoluble and Mo oxides are soluble in water, the dipping procedure of the sample in de-ionized water will help with the complete detachment of the topmost oxidized MoS₂ layer. Afterwards, with a re-sulfurization procedure after the removal of topmost oxidized MoS₂ layer, the partially oxidized MoS₂ film remaining on the substrate can be recovered back to a complete MoS₂ film. Both optical and electrical characteristics of the MoS₂ films can be maintained after the removal procedure. By repeating the ALE cycle, a layer-by-layer removal of MoS₂ can be achieved (e.g., see the 2-D material layers 130a and 130b in FIG. 8). In some embodiments, each ALE cycle may remove one mono-layer of the 2-D material layer 130.

Reference is made to FIG. 3. A metal layer 140 is deposited over the patterned mask M1 and overfilling the openings O1 of the patterned mask M1. In some embodiments, the metal layer 140 is in contact with the 2-D material layer 120. Accordingly, the bottommost surface of the metal layer 140 is lower than the top surface 132 of the 2-D material layer 130 and the bottom surface of the patterned mask M1.

In some embodiments, blanket conductive layers may be formed on the patterned mask M1 by deposition processes such as CVD, PVD, ALD, combinations thereof, or the like to form the metal layer 140. In some embodiments, the metal layer 140 is formed at a temperature in a range between room temperature and about 200° C. In some embodiments, the metal layer 140 includes a conductive material layer that includes a refractory metal or its compounds, e.g., tungsten (W), titanium (Ti), titanium nitride (TiN), titanium tungsten (TiW), or other suitable materials. In some other embodiments, the metal layer 140 includes nickel (Ni), gold (Au), aluminum (Al), silver (Ag), or copper (Cu). In some embodiments, the metal layer 140 includes a first layer made of a first metal, and a second layer made of a second metal over the first layer, in which the first metal and the second metal are made of different materials. For example, the first metal may be titanium (Ti) having a thickness in a range from about 15 nm to about 25 nm, and the second metal may be gold (Au) having a thickness in a range from about 90 nm to about 110 nm. The metal layer 140 may be depositing by using e-beam deposition process, ALD process, or combinations thereof. In still some other embodiments, the metal layer 140 is semimetals, e.g., antimonene, stanene, combinations thereof, or the like.

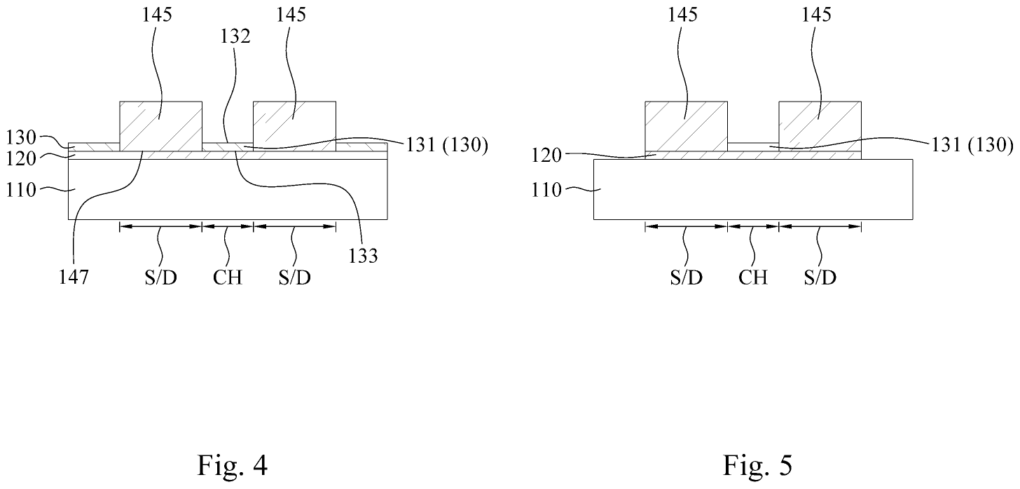

Reference is made to FIG. 4. The patterned mask M1 may be removed, while leaving portions of the metal layer 140 (see FIG. 3) remaining over the 2-D material layer 120 and covering the source/drain regions S/D of the 2-D material layer 120. In some embodiments, the remaining portions of the metal layer 140 are substantially align with the source/drain regions S/D of the 2-D material layer 120, respectively, and the remaining portions of the metal layer 140 may be referred to as source/drain contacts 145. In some embodiments, the top surface of each source/drain contact 145 is higher than the top surface 132 of the portion 131 of the 2-D material layer 130, while the bottom surface 147 of each source/drain contact 145 may be level with the bottom surface 133 of the portion 131 of the 2-D material layer 130.

Reference is made to FIG. 5. The 2-D material layer 120 is patterned to define an active layer of the 2-D material layer 120. In greater details, portions of the 2-D material layer 120 other than the channel region CH and the source/drain regions S/D are removed during the patterning process. For example, portions of the 2-D material layer 120 under the source/drain contacts 145 and portions of the 2-D material layer 120 between the source/drain contacts 145 are protected during the patterning process and remain over the substrate 110 after the patterning process.

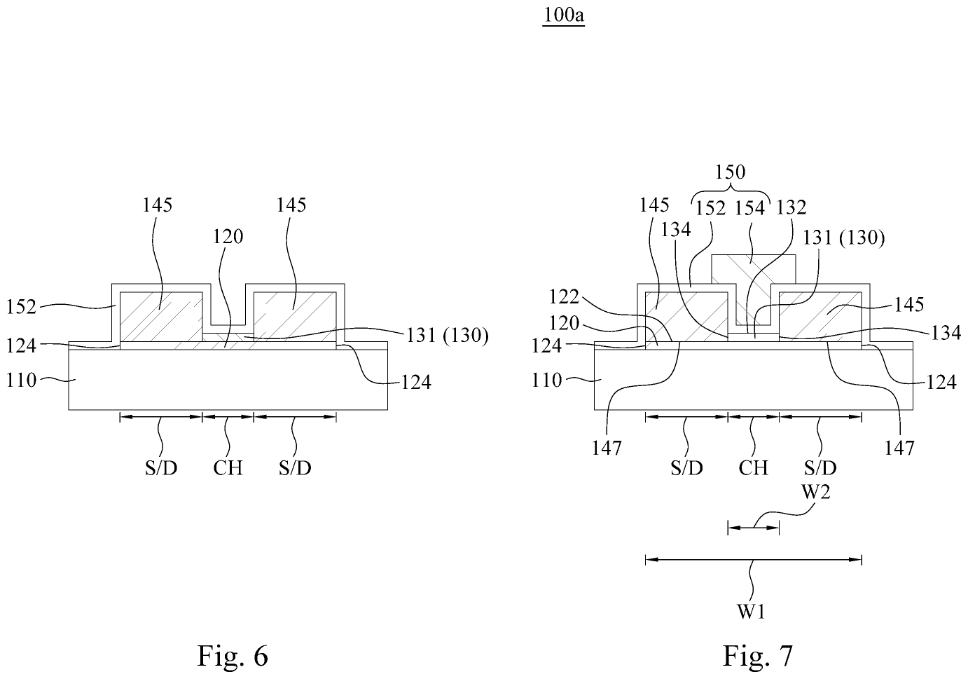

Reference is made to FIG. 6. A gate dielectric layer 152 is formed over the substrate 110. In greater details, the gate dielectric layer 152 is formed in contact with the 2-D material layer 131 and covering the channel region CH of the 2-D material layer 120. Moreover, the gate dielectric layer 152 is formed lining opposite sidewalls of each source/drain contacts 145, lining opposite sidewalls 124 of the 2-D material layer 120, and further extending to exposed surface of the substrate 110.

The gate dielectric layer 152 may be made of oxide materials, e.g., SiO₂, Al₂O₃, HfO₂, combinations thereof, or the like. In some embodiments where the gate dielectric layer 152 is made of aluminum oxide (Al₂O₃), the gate dielectric layer 152 made be formed by depositing a first Al₂O₃ film by e-beam deposition, and then depositing a second Al₂O₃ film by ALD process. The e-beam deposition is a physical deposition process that can deposit the Al₂O₃ film over the substrate, and the precursors of the following ALD process can properly adhere to the surface of the pre-deposited Al₂O₃ film, therefore ensuring a better film distribution over the substrate. In some embodiments, the gate dielectric layer 152 has a thickness in a range from about 3 nm to about 30 nm.

Reference is made to FIG. 7. A gate electrode 154 is formed over the gate dielectric layer 152. The gate electrode 154 is formed covering the channel region CH of the 2-D material layer 120, and further extending to positions vertically above the top surfaces of the source/drain contacts 145. The gate dielectric layer 152 and the gate electrode 154 may be collectively referred to as a gate structure 150.

In some embodiments, a blanket conductive layer may be formed on the gate dielectric layer 152 in advance by a deposition process such as CVD, PVD, ALD, combinations thereof, or the like, and then a patterning process is performed to pattern the blanket conductive layer to form the gate electrode 154 between the source/drain contacts 145. In some embodiments, the gate electrode 154 includes a conductive material layer that includes a refractory metal or its compounds, e.g., tungsten (W), titanium (Ti), titanium nitride (TiN), titanium tungsten (TiW), or other suitable materials. In some other embodiments, the gate electrode 154 includes nickel (Ni), gold (Au), aluminum (Al), silver (Ag), or copper (Cu). In still some other embodiments, the gate electrode 154 is a gate stack including the conductive materials mentioned above and further one or more dielectric such as SiO₂, high-k dielectric (e.g., HfO₂), ferroelectric materials (e.g., HZO), or other suitable materials. For example, the gate electrode 154 has materials substantially the same as the source/drain contact 145, e.g., a first layer made of a first metal (e.g., Ti), and a second layer made of a second metal (e.g., Au) over the first layer. For example, the first metal has a thickness in a range from about 15 nm to about 25 nm, and the second metal has a thickness in a range from about 90 nm to about 110 nm.

In FIG. 7, the memory device 100a includes the substrate 110, the 2-D material layer 120, the 2-D material layer 130, the source/drain contacts 145, the gate dielectric layer 152, and the gate electrode 154. The 2-D material layer 120 is over the substrate 110, and the 2-D material layer 130 is over the 2-D material layer 120. A width W1 of the 2-D material layer 120 is greater than a width W2 of the 2-D material layer 130.

The source/drain contacts 145 are over the 2-D material layer 120 and on opposite sidewalls 134 of the 2-D material layer 130. Specifically, the source/drain contacts 145 are in contact with the top surface 122 of the 2-D material layer 120. The gate dielectric layer 152 covers the source/drain contacts 145 and the 2-D material layer 130. Further, the gate dielectric layer 152 is in contact with the sidewalls 124 of the 2-D material layer 120. However, the gate dielectric layer 152 is spaced apart from the sidewalls 134 of the 2-D material layer 130 (131). The bottom surfaces 147 of the source/drain contacts 145 are lower than a top surface 132 of the 2-D material layer 130. The gate electrode 154 is over the gate dielectric layer 152 and directly over the 2-D material layer 130. Specifically, the gate dielectric layer 152 is between the gate electrode 154 and the 2-D material layer 130.

FIG. 8 illustrates a cross-sectional view of a memory device 100b in accordance with some embodiments of the present disclosure. The difference between the memory devices 100b and 100a (see FIG. 7) pertains to the number of channel layers. Specifically, the memory device 100b includes a plurality of channel layers (e.g., the 2-D material layers 120a and 120b). In some embodiments, the 2-D material layers 120a and 120b are made of the same materials. In some other embodiments, the 2-D material layers 120a and 120b are made of different materials having a band gap difference lower than about 0.5 eV. For example, the 2-D material layers 120a and 120b includes the same chalcogen atoms and different transition metals. Other relevant structural details of the memory device 100b in FIG. 8 are similar to the memory device 100a in FIG. 7, and, therefore, a description in this regard will not be repeated hereinafter.

FIG. 9 illustrates a cross-sectional view of a memory device 100c in accordance with some embodiments of the present disclosure. The difference between the memory devices 100c and 100a (see FIG. 7) pertains to the number of charge storage layers. Specifically, the memory device 100c includes a plurality of charge storage layers (e.g., the 2-D material layers 130a and 130b). The portions 131a and 131b are located below the gate electrode 154. In some embodiments, the 2-D material layers 130a and 130b are made of the same materials. In some other embodiments, the 2-D material layers 130a and 130b are made of different materials having a band gap difference lower than about 0.5 eV. For example, the 2-D material layers 130a and 130b includes the same chalcogen atoms and different transition metals. Other relevant structural details of the memory device 100c in FIG. 9 are similar to the memory device 100a in FIG. 7, and, therefore, a description in this regard will not be repeated hereinafter.

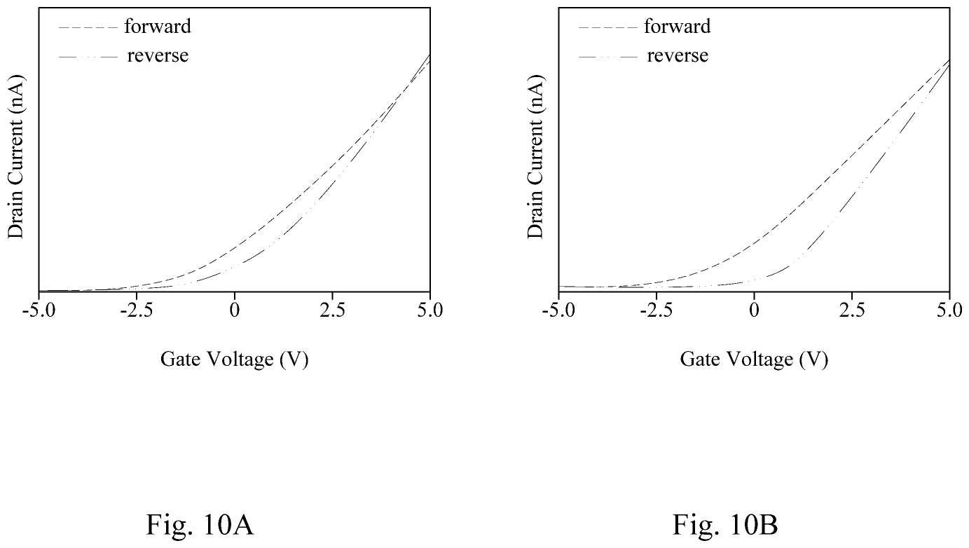

FIG. 10A illustrates an I_{D}-V_{GS} curve of the memory device shown in FIG. 8, and FIG. 10B illustrates an I_{D}-V_{GS} curve of the memory device shown in FIG. 9. The forward and reverse transfer curves of the memory devices 100b and 100c of FIGS. 8 and 9 at V_{DS}=1.0 V are shown. As shown in the figures, hysteresis loops are observed for the devices. A possible mechanism for this phenomenon is the build-in potential resulted from the charged MoS₂ layer (e.g., the 2-D material layers 131, 131a, and/or 131b). For example, higher drain (electron) currents are observed for the device under forward gate biases due to the electron depletion at negative gate biases. Further, as the number of the charge storage layers increases, the hysteresis effect is more obvious, which may be attributed to the more storage room of electrons in the 2-D material layers 131a and 131b. The results suggest that the MoS₂ layer between the source/drain contacts 145 (e.g., the 2-D material layers 131, 131a, and/or 131b) may act as an effect charge storage layer. Further, the memory device 100c has a reduced drain current level than that of the memory device 100b, which may be attributed to the single channel layer in the memory device 100c (compared with the two layers of the channel layers in the memory device 100b).

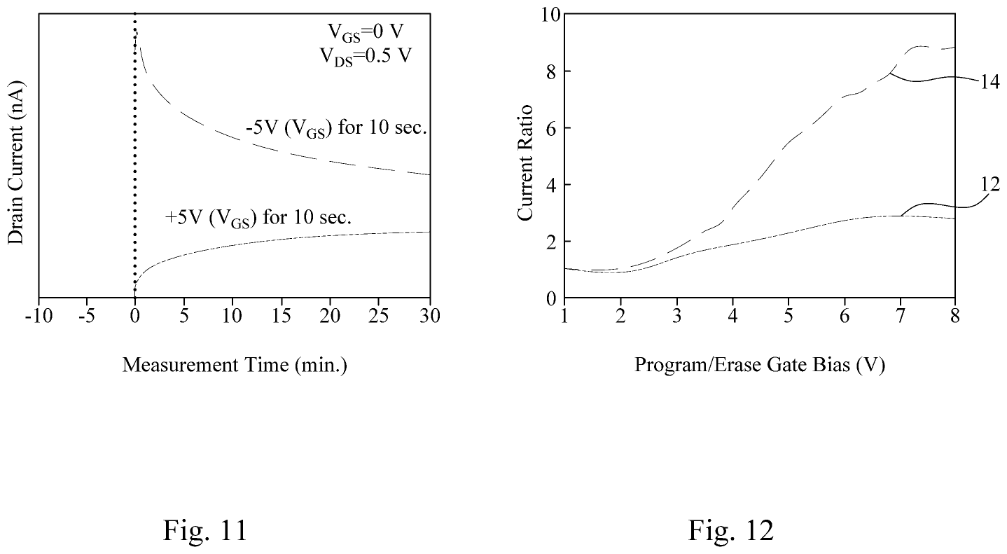

FIG. 11 illustrates an I_{D}-measurement time curve of the memory device shown in FIG. 10B. As shown in the figure, after a +5.0 V gate voltage applied to the device for about 10 sec., lower drain (electron) currents are observed for the device at V_{GS}=0 V. After a −5.0 V gate voltage applied to the device for about 10 sec., higher drain (electron) currents are observed. The (electron) current separation is kept up to tens of seconds. The results are consistent with the observation from the device's transfer curve of FIG. 10B. When the MoS₂ layers (e.g., the 2-D material layers 131a and 131b) are charged with electrons (positive gate biases; erase), a “0” state is observed for the device at V_{GS}=0 V. When electrons are depleted from the MoS₂ layer (negative gate biases; write), a “1” state is observed for the device at V_{GS}=0 V. The long retention time for the “0” and “1” states of the device suggests that an effective electron storage in the isolated MoS₂ layers. The van der Waals interface between the layers 120 and 131a-131b will prevent charge transfer when no external electrical fields are applied to the charge storage layers.

FIG. 12 illustrates a current ratio-V_{GS} curve of the memory devices 100b and 100c shown in FIGS. 8 and 9. In FIG. 12, the current ratio defines a drain (electron) current (I_{D}) in state “1” to an I_{D} in state “0” under about 5 sec of write/erase time. As shown in FIG. 12, both the memory devices 100b (curve 12) and 100c (curve 14) perform a significant difference between the two states “1” and “0”. Further, under high gate biases (e.g., greater than about 3 V), the current ratio is not proportional to the numbers of the 2-D material layers 131 (131a and 131b). It might be that fewer electrons are stored in the topmost 2-D material layer 131b than in the 2-D material layer 131a due to the existence of the gate dielectric layer 152.

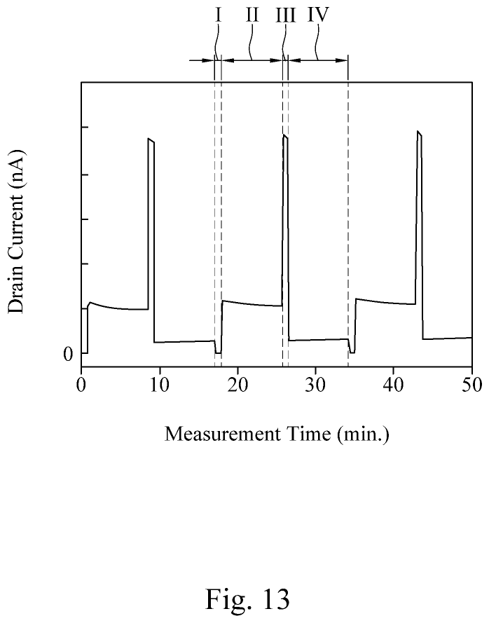

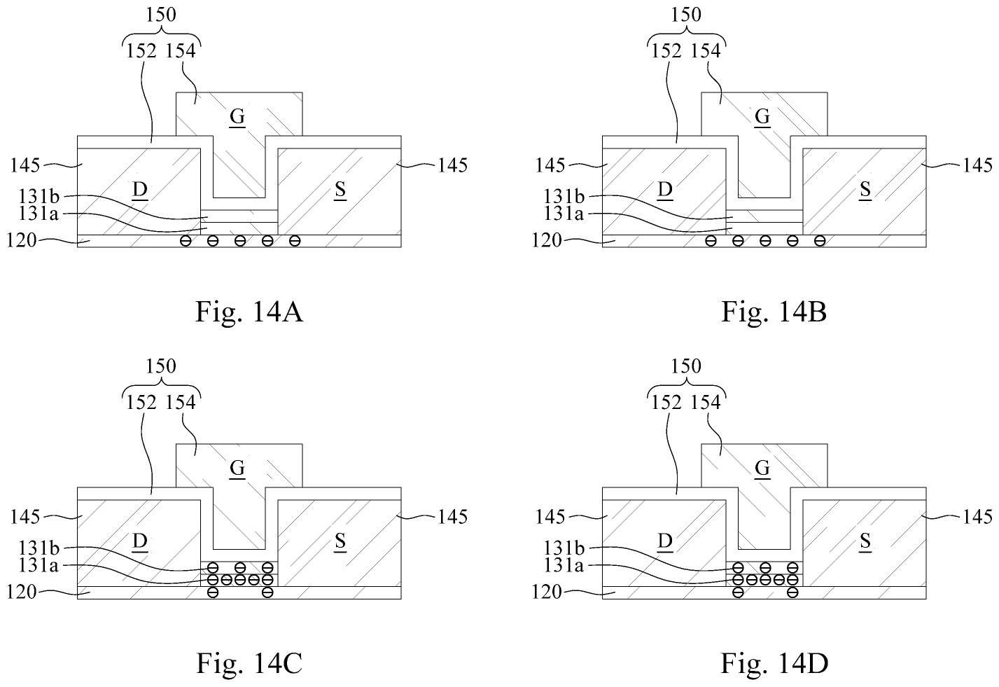

FIG. 13 illustrates an I_{D}-measurement time curve of the memory device 100c shown in FIG. 9. FIGS. 14A, 14B, 14C, and 14D illustrate (electron) current conduction mechanism at different stages in accordance with some embodiments of the present disclosure. Referring to FIGS. 13 and 14A, in stage I of FIG. 13, a write operation is performed. When a negative gate bias (e.g., about −5V) is applied (less than about 1.0 sec.), electrons will be depleted in the isolated MoS₂ layer (e.g., the 2-D material layer 131), and an n-type channel is observed as shown in FIG. 14A. Referring to FIGS. 13 and 14B, in stage II of FIG. 13, a read operation is performed under a zero gate bias. A higher electron density and such that a higher drain (electron) current will be observed with applied drain voltages, which will correspond to a “1” state. Referring to FIGS. 13 and 14C, in stage III of FIG. 13, an erase operation is performed. When a positive gate bias (e.g., about +5V) is applied (less than about 1.0 sec.), electrons are stored in the isolated MoS₂ layer (e.g., the 2-D material layer 131). Referring to FIGS. 13 and 14D, in stage IV of FIG. 13, a read operation is performed. A lower drain (electron) current is observed when the same drain voltage is applied. This will correspond to a “0” state for the memory device. Consequently, the applied negative and positive gate biases would correspond to write and erase process of the memory devices, respectively. The repeating operation of the device also indicates a potential application for a memory device.

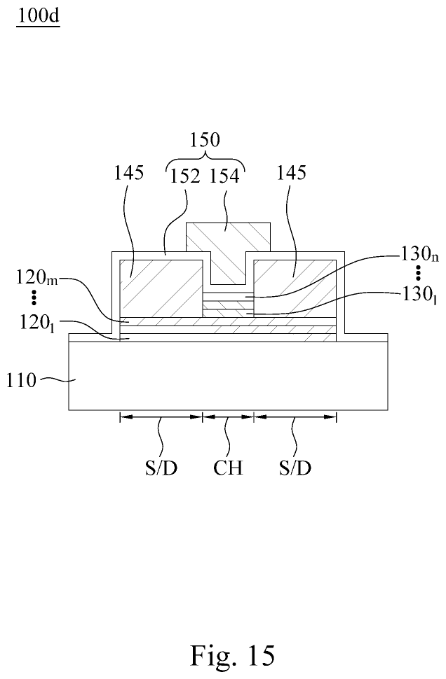

FIG. 15 illustrates a cross-sectional view of a memory device 100d in accordance with some embodiments of the present disclosure. The difference between the memory devices 100d and 100a (see FIG. 7) pertains to the number of charge storage layers and the number of channel layers. Specifically, the memory device 100d includes a plurality of channel layers (e.g., the 2-D material layers 120₁-120ₘ) and a plurality of charge storage layers (e.g., the 2-D material layers 131₁-131ₙ). In some embodiments, the 2-D material layers 120₁-120ₘ are made of the same materials. In some other embodiments, the 2-D material layers 120₁-120ₘ are made of different materials having a band gap difference lower than about 0.5 eV. For example, the 2-D material layers 120₁-120ₘ includes the same chalcogen atoms and different transition metals. The portions 131₁-131ₙ are located below the gate electrode 154. In some embodiments, the 2-D material layers 131₁-131ₙ are made of the same materials. In some other embodiments, the 2-D material layers 131₁-131ₙ are made of different materials having a band gap difference lower than about 0.5 eV. For example, the 2-D material layers 131₁-131ₙ includes the same chalcogen atoms and different transition metals. The 2-D material layers 120₁-120ₘ and the 2-D material layers 131₁-131ₙ may be made of the same material or different materials. Moreover, the layer number of the 2-D material layers 131₁-131ₙ is greater than the layer number of the 2-D material layers 120₁-120ₘ. That is, n is greater than m. In some embodiments, n+m is in a range from 2 to about 20, and n is in a range from 1 to about 19. Other relevant structural details of the memory device 100d in FIG. 15 are similar to the memory device 100a in FIG. 7, and, therefore, a description in this regard will not be repeated hereinafter.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the 2-D materials with similar band gaps can be used to be both charge storage layer(s) and channel layer(s) of memory devices, and long retention time for the “0” and “1” states can be observed. Further, the 2-D materials with similar band gaps can simplify the manufacturing process. In addition, the 2-D materials are thin and the possible 1T0C architecture can effectively reduce the physical dimension of the memory devices. Moreover, the same current levels of the “0” and “1” states in the multi operation cycles suggest a stable performance of the memory devices.

According to some embodiments, a memory device includes a substrate, a 2-D material channel layer, a 2-D material charge storage layer, source/drain contacts, a gate dielectric layer, and a gate electrode. The 2-D material channel layer is over the substrate. The 2-D material charge storage layer is over the 2-D material channel layer. The 2-D charge storage layer and the 2-D material channel layer include the same chalcogen atoms. The source/drain contacts are over the 2-D material channel layer. The gate dielectric layer covers the source/drain contacts and the 2-D material charge storage layer. The gate electrode is over the gate dielectric layer.

According to some embodiments, a memory device includes a substrate, a 2-D material channel layer, a 2-D material charge storage layer, source/drain contacts, a gate dielectric layer, and a gate electrode. The first 2-D material channel layer is over the substrate. The first 2-D material charge storage layer is over the first 2-D material channel layer. A difference between band gaps of the first 2-D material channel layer and the first 2-D material charge storage layer is smaller than about 0.5 eV. The source/drain contacts are on opposite sidewalls of the first 2-D material charge storage layer and in contact with a top surface of the first 2-D material channel layer. The gate electrode is directly over the first 2-D material charge storage layer. The gate dielectric layer is between the gate electrode and the first 2-D material charge storage layer.

According to some embodiments, a method includes forming a 2-D material channel layer over a substrate; forming a 2-D material charge storage layer over the 2-D material channel layer; forming a patterned mask having openings exposing the 2-D material charge storage layer; removing portions of the 2-D material charge storage layer by using the patterned mask as an etch mask; forming source/drain contacts in the openings of the patterned mask; removing the patterned mask; and forming a gate structure over the 2-D material channel layer and between the source/drain contacts.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device comprising:
a substrate;
a 2-D material channel layer over the substrate;
a 2-D material charge storage layer over the 2-D material channel layer, wherein the 2-D material charge storage layer and the 2-D material channel layer comprise the same chalcogen atoms;
source/drain contacts over the 2-D material channel layer;
a gate dielectric layer covering the source/drain contacts and the 2-D material charge storage layer; and
a gate electrode over the gate dielectric layer.

2. The memory device of claim 1, wherein the 2-D material channel layer further comprises transition metals.

3. The memory device of claim 1, wherein the 2-D material charge storage layer further comprises transition metals.

4. The memory device of claim 1, wherein the gate dielectric layer is in contact with a sidewall of the 2-D material channel layer.

5. The memory device of claim 1, wherein the gate dielectric layer is spaced apart from a sidewall of the 2-D material charge storage layer.

6. The memory device of claim 1, wherein a width of the 2-D material channel layer is greater than a width of the 2-D material charge storage layer.

7. The memory device of claim 1, wherein a bottom surface of one of the source/drain contacts is lower than a top surface of the 2-D material charge storage layer.

8. A memory device comprising:
a substrate;
a first 2-D material channel layer over the substrate;
a first 2-D material charge storage layer over the first 2-D material channel layer, wherein a difference between band gaps of the first 2-D material channel layer and the first 2-D material charge storage layer is smaller than about 0.5 eV;
source/drain contacts on opposite sidewalls of the first 2-D material charge storage layer and in contact with a top surface of the first 2-D material channel layer;
a gate electrode directly over the first 2-D material charge storage layer; and
a gate dielectric layer between the gate electrode and the first 2-D material charge storage layer.

9. The memory device of claim 8, wherein the first 2-D material channel layer and the first 2-D material charge storage layer are made of the same material.

10. The memory device of claim 8, wherein the first 2-D material channel layer and the first 2-D material charge storage layer are transition metal dichalcogenides (TMDs).

11. The memory device of claim 8, wherein the band gap of the first 2-D material charge storage layer is greater than the band gap of the first 2-D material channel layer.

12. The memory device of claim 8, further comprising a second 2-D material channel layer between the substrate and the first 2-D material channel layer.

13. The memory device of claim 8, further comprising a second 2-D material charge storage layer between the first 2-D material charge storage layer and the first 2-D material channel layer.

14. The memory device of claim 13, wherein the first 2-D material charge storage layer and the second 2-D material charge storage layer are made of the same material.

15. A method comprising:
forming a 2-D material channel layer over a substrate;
forming a 2-D material charge storage layer over the 2-D material channel layer;
forming a patterned mask having openings exposing the 2-D material charge storage layer;
removing portions of the 2-D material charge storage layer by using the patterned mask as an etch mask;
forming source/drain contacts in the openings of the patterned mask;
removing the patterned mask; and
forming a gate structure over the 2-D material channel layer and between the source/drain contacts.

16. The method of claim 15, wherein the 2-D material channel layer and the 2-D material charge storage layer comprise the same chalcogen atoms.

17. The method of claim 15, wherein removing portions of the 2-D material charge storage layer is performed by using an atomic layer etching process.

18. The method of claim 15, wherein after removing portions of the 2-D material charge storage layer, the 2-D material channel layer is exposed by the openings.

19. The method of claim 15, wherein the source/drain contacts are formed over the 2-D material channel layer.

20. The method of claim 15, wherein band gaps of the 2-D material channel layer and the 2-D material charge storage layer are both in a range from about 1 eV to about 3 eV.
